(19) United States
(12) Patent Application Publication
(10) Pub. No.: US 2007/0090430 A1
(43) Pub. Date: Apr. 26, 2007

(54) Semiconductor memory device

(75) Inventors: Masayuki Nakano, Nara-shi (JP); Hiroshi Iwata, Ikoma-gun (JP); Akihide Shibata, Nara-shi (JP)

Correspondence Address: BIRCH STEWART KOLASCH & BIRCH, PO BOX 747, FALLS CHURCH, VA, 22040-0747, US

(73) Assignee: Sharp Kabushiki Kaisha, Osaka-shi (JP)

(21) Appl. No.: 11/581,352

(22) Filed: Oct. 17, 2006

(30) Foreign Application Priority Data
Oct. 17, 2005 (JP) 2005-301793

(51) Int. Cl. H01L 29/94; H01L 29/788; H01L 27/108; H01L 29/76; H01L 31/119

(52) U.S. Cl. 257/296; 257/316

(57) ABSTRACT

semiconductor memory device comprising: a semiconductor layer; a gate electrode formed on the semiconductor layer through a gate insulating film; a channel region provided beneath the gate electrode; source/drain diffusion regions having a conductivity type opposite to that of the channel region and provided on both sides of the channel region; and memory function bodies having a function of holding a charge and formed on at least both sides of the gate electrode, wherein the memory function body is formed of a charge holding film and a tunnel insulating film, the tunnel insulating film exists on the side wall portion of the gate electrode and between the charge holding film and the semiconductor layer, and the tunnel insulating film between the charge holding film and the semiconductor layer is thicker than the tunnel insulating film between the charge holding film and the side wall portion of the gate electrode.

### CROSS-REFERENCE TO RELATED APPLICATION

This application is related to Japanese application 2005-301793 filed on Oct. 17, 2005, whose priority is claimed under 35 USC § 119, the disclosure of which is incorporated by reference in its entirety.

### BACKGROUND OF THE INVENTION

1. Field of the Invention

The present invention relates to a semiconductor memory device. In particular, the invention relates to a semiconductor memory device that can be miniaturized.

2. Description of the Related Art

Nonvolatile memories where two bits can be stored on both sides of a gate electrode have been proposed (for example in Japanese Unexamined Patent Publication 2003-332474, Japanese Unexamined Patent Publication HEI 9 (1997)-116119 and Japanese Unexamined Patent Publication 2001-156188). FIG. 9 shows the structure of a typical semiconductor memory device (memory cell) which forms nonvolatile memories in these publications. In FIG. 9, 301 indicates a semiconductor substrate, 302 indicates a gate insulating film, 303 indicates a gate electrode (word line), 304 indicates tunnel insulating films, 306 indicates silicon nitride films, which are memory storing portions, 307 indicates silicon oxide films, 308 indicates source/drain regions, 330 indicates offset regions, and 331 indicates a channel region directly beneath the gate electrode, respectively.

This memory cell is an element having an offset structure where the source/drain regions 308 are at a distance from the gate electrode 303, that is to say, there are offset regions 330. In addition, memory function bodies formed of three layers; a tunnel insulating film 304, a silicon nitride film 306 and a silicon oxide film 307, are provided. Here, the resistance in the offset regions changes on the basis of whether or not electrons are held in the silicon nitride film 306. Together with change in this resistance the driving current also changes, and thereby, recording of information of “0” and “1” is implemented. In practice, a specific word line (gate electrode) and bit line (drain electrode) are selected in the memory cell array, which is formed by aligning memory cells, and predetermined voltages are applied, and thereby, rewriting and read-out operations can be carried out on a desired memory cell.

### SUMMARY OF THE INVENTION

The present invention provides a semiconductor memory device comprising:

a semiconductor layer;

a gate electrode formed on the semiconductor layer through a gate insulating film;

a channel region provided beneath the gate electrode;

source/drain diffusion regions having a conductivity type opposite to that of the channel region and provided on both sides of the channel region; and

memory function bodies having a function of holding a charge and formed on at least both sides of the gate electrode,

wherein the memory function body is formed of a charge holding film and a tunnel insulating film,

the tunnel insulating film exists on the side wall portion of the gate electrode and between the charge holding film and the semiconductor layer, and

the tunnel insulating film between the charge holding film and the semiconductor layer is thicker than the tunnel insulating film between the charge holding film and the side wall portion of the gate electrode.

According to the semiconductor memory device as described, the memory function bodies are formed independently of the gate insulating film, and are formed on both sides of the gate electrode. Therefore, a two-bit operation is possible. Furthermore, the memory function bodies are separated from each other by the gate electrode, and therefore, interference at the time of rewriting can be effectively restricted.

In addition, the tunnel insulating film between the charge holding films and the semiconductor layer has a film thickness that is greater than that of the tunnel insulating film on the side wall portion of the gate electrode, and therefore, increase in the current on the program side can be restricted while restricting gate disturbance. Accordingly, the gate can be formed so as to have a small gate width, and thus, memory cells can be miniaturized and a highly integrated nonvolatile memory can be implemented.

In addition, it is preferable for the charge holding film to be made of an insulating material and for the memory function body to be formed so as to at least partially overlap a portion of the above described source/drain diffusion regions.

As described, the memory function body is formed of an insulating material, and therefore, the manufacturing process for memory cell can be simplified and the yield increased. In the case where the memory function body is s conductor, an additional step for electrically separating the memory function bodies for each cell so that an adjacent memory cell does not shot-circuit becomes necessary, increasing the number of manufacturing steps, and the cost increases. In addition, when memory cells are integrated, adjacent memory cells do not interfere with each other. Furthermore, the memory function bodies are formed on at least the walls on both sides of the gate electrode so as to at least partially overlap with a portion of the source and drain diffusion regions, and the source/drain diffusion regions in the vicinity of the gate electrode are formed to be shallow. Therefore, miniaturization of memory cell becomes easier. On top of this, program operation into a memory cell can be appropriately carried out.

In addition, it is preferable for the gate electrode and the source/drain diffusion regions to be at a distance from each other in the direction of the gate length.

Thus, the gate electrode and the source/drain diffusion regions form an offset structure, and therefore, the efficiency of injection of a charge into a memory function body increases, and the speed of program and erase can be increased.

In addition, the tunnel insulating film between the charge holding films and the semiconductor layer can be made 1.25 to 4 times thicker than the tunnel insulating film on the side wall portion of the gate electrode.

Thus, the thickness of the tunnel insulating films is optimized, and therefore, the effects of restricting gate disturbance and of restricting increase of the current on the program side can be enhanced. Accordingly, the gate can be formed so as to have a smaller width, and thus, memory cells can be miniaturized and a highly integrated nonvolatile memory can be implemented.

These and other objects of the present application will become more readily apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 is a schematic cross section of a semiconductor memory device according to the present invention (embodiment 1);

FIG. 2 is a schematic cross section of a modified semiconductor memory device according to the present invention (embodiment 1);

FIG. 3 is a schematic cross section for illustrating a detail portion of a semiconductor memory device according to the present invention (embodiment 1);

FIG. 4 is a schematic cross section of a modified semiconductor memory device according to the present invention (embodiment 1);

FIG. 5 is a schematic cross section of a semiconductor memory device according to the present invention (embodiment 2);

FIG. 6 is a schematic cross section of a semiconductor memory device according to the present invention (embodiment 3);

FIGS. 7A to 7D are views for illustrating the manufacturing method for the semiconductor memory device (embodiment 3);

FIGS. 8A to 8C are views for illustrating the manufacturing method for the semiconductor memory device (embodiment 3);

FIG. 9 is a schematic cross section of a semiconductor memory device according to the prior art.

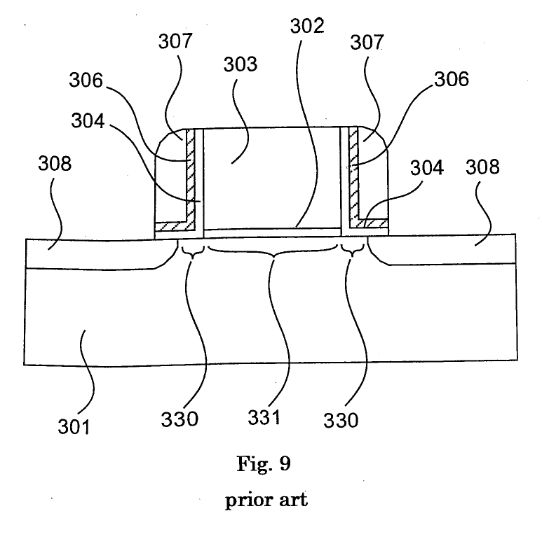

### DESCRIPTION OF THE PREFERRED EMBODIMENT

In the nonvolatile memory cells of the above mentioned publications, gate disturbance, which is a phenomenon where a current on the erase side (stored information “0”) becomes inferior, occurs in an unselected cell. This phenomenon is described in the following.

One word line (gate electrode) is shared by 1000 to 4000 memory cells in order to reduce the chip area, where memory cells are in an array. When a desired memory cell is selected, a voltage of approximately 3 V is applied to the word lines of unselected cells other than the selected cell. Accordingly, a voltage of 3 V is continuously applied to the gate electrodes of the unselected cells for a long period of time. Therefore, electrons in the silicon substrate enter into a silicon nitride film as a result of the gate voltage, thus the threshold voltage of the offset region increases and the current for erase reduces. The inventors found from experiments that this amount of reduced current is proportional to the logarithm of time (log (t); t is time).

Therefore, the inventors examined the tunnel insulating film 304, in order to find a manner to restrict this phenomenon. As a result of much examination, it was found that this phenomenon can particularly be restricted by reducing the film thickness of the tunnel insulating film 304. When, for example, the film thickness of the tunnel insulating film 304 was approximately 6 nm to 8 nm, the deterioration was 4 μA/unit to 5 μA/unit. However, the deterioration could be restricted to 1 μA/unit to 2 μA/unit by setting the film thickness at 2 nm to 4 nm. Here, the gate length of the memory cells used for this evaluation was 0.18 μm, and the gate width was 0.38 μm. All of the data shown in the following is data on memory cells having these dimensions.

Gate disturbance occurs when stress at the time of thermal oxidation causes traps to be created in the tunnel insulating films 304, through which tunneling electrons easily pass. Accordingly, it is considered that traps can be released by reducing the film thickness, and thereby, reduction in current also becomes small.

When the tunnel insulating films 304 are made thinner, however, a new phenomenon, so-called “initial deterioration,” becomes significant. This is a phenomenon where the current value on the program side of stored information “1” increases. When heat is applied to a memory cell for a short period of time, for example 250° C. for 6 minutes, the current value increases to 30 μA to 40 μA. This is because the electrons in the silicon nitride films 306 are released into the semiconductor substrate, thus lowering the threshold voltage.

As described above, when gate disturbance is restricted, a reciprocal phenomenon occurs, where increase in the current on the program side becomes significant. As a result, gate disturbance cannot be restricted simply by reducing the thickness of the tunnel insulating film 304, and thus, the cell area cannot be reduced.

Meanwhile, it is generally necessary to guarantee that a difference in the current for read-out (memory window) will remain after ten years in the nonvolatile memory. When the amount of reduced current after ten years is calculated, 4 μA/unit to 5 μA/unit×8.5 units (corresponding to ten years)=34 μA to 42.5 μA. This reduced amount is very large and becomes a factor in hindering the miniaturization of memory cell. That is to say, it is necessary for memory cell to be able to secure a current of which the value is equal to that when the above described amount of reduced current is added to the memory window for reading out stored information of “0” or “1,” in order to make the memory operation possible even after ten years.

In the prior art, the amount of reduced current was compensated for by increasing the gate width. Accordingly, the area occupied by the memory increases as the gate width is increased, and miniaturization of memory cell is hindered.

The present invention is provided in view of the above described problems, and an object of the invention is to provide a semiconductor memory device (memory cell) which can be integrated to a high degree by miniaturizing the cell area.

It is preferable for a semiconductor memory device (memory cell) of the present invention to be formed on a semiconductor substrate which is used as a semiconductor layer.

The semiconductor substrate is not particularly limited, as long as it can be used for a semiconductor device, and bulk substrates, including those of element semiconductors, such as silicon and germanium, and compound semiconductors, such as silicon germanium, GaAs, InGaAs, ZnSe and GaN, can be cited as examples. In addition, a variety of substrates, such as SOI (silicon on insulator) substrates, SOS substrates and multilayer SOI substrates, as well as those having a semiconductor layer on a glass or plastic substrate may be used as a semiconductor substrate having a semiconductor layer on the surface. From among these, silicon substrates and SOI substrates where a silicon layer is formed on the surface are preferable. The semiconductor substrate or semiconductor layer may be any of single crystal (for example, epitaxially grown one), polycrystal or amorphous, though there is a slight difference in the amount of current that flows inside.

It is preferable for an element isolation region to be formed on this semiconductor layer, and furthermore, a single or multilayer structure may be provided by combining elements such as transistors, capacitors and resistors, and circuits and semiconductor devices made of these, as well as interlayer insulating films. Here, the element isolation region can be formed of a variety of element isolation films, such as LOCOS films, trench oxide films and STI films. The semiconductor layer may have a conductivity type of P type or N type, and it is preferable for at least one well region of a first conductivity type (P type or N type) to be formed in the semiconductor layer. As for the impurity concentration in the semiconductor layer and the well region, a range well known in the art can be selected. Here, in the case where an SOI substrate is used as the semiconductor layer, a well region may be formed in the semiconductor layer on the surface, and a body region may be provided beneath the channel region.

The gate insulating film is not particularly limited, as long as it can be used in a conventional way for a semiconductor device, and, for example, insulating films such as silicon oxide film and silicon nitride film, as well as single layer film and multilayer film of aluminum oxide film, titanium oxide film, tantalum oxide film, hafnium oxide film and high dielectric film, such as of aluminum hafnium oxide, can be used. Among these, silicon oxide film is preferable. It is appropriate for the gate insulating film to have a film thickness of, for example, approximately 1 nm to 20 nm, preferably 1 nm to 6 nm (converted to the value for a silicon oxide film through calculation).

The gate electrode is formed on the gate insulating film so as to have a form that is conventionally used for semiconductor devices or a form having a recess on the lower end portion. Here, the gate electrode may be formed of a single layer or multilayer conductive film so as to have an integrated form without being separated, or may be formed of a single layer or multilayer conductive film in a separated state. The gate electrode is not particularly limited, as long as it can be used in a conventional way for semiconductor devices, and conductive single layer films and multilayer films, such as polysilicon, metals, including copper and aluminum, high melt point metals, including tungsten, titanium and tantalum, and silicide of a high melt point metal can be cited as examples. It is appropriate for the gate electrode to be formed so as to have a film thickness of, for example, approximately 50 nm to 400 nm. Here, a channel region is formed beneath the gate electrode. In the case where the technology node is 180 nm, for example, it is preferable for the length of the gate electrode in the direction of the channel length to be 110 nm to 180 nm, and it is preferable for the length of the channel region in the direction of the channel width (gate width) to be 180 nm to 400 nm. Here, the gate width may be below the above described range in the case of a specification where the memory windows are small, that is to say, the speed of read out may be slow. The gate width may be above the above described range in the case of a specification where a high speed operation is required, and the cell area may be large, to some extent.

Here, it is preferable for the gate electrode to be formed only on the side wall of the below described memory function body or not to cover the upper portion of the memory function body. Such an arrangement allows the contact plug to be placed proximate to the gate electrode, and therefore, miniaturization of the memory cell becomes easy. In addition, the manufacture of a memory cell having such a simple arrangement is easy, and the yield can be increased.

The memory function body has at least a function of holding a charge (hereinafter referred to as “charge holding function”). In other words, the memory function body has a function of storing and holding a charge, trapping a charge, or holding the polarized state of a charge. This function is achieved when the memory function body includes a charge holding film. As for materials that can allow this function to be achieved, silicon nitrides, silicon, silicate glass which includes an impurity, such as phosphorous or boron, silicon carbide, alumina, high dielectric substances, such as hafnium oxide, zirconium oxide and tantalum oxide, zinc oxide, ferroelectric substances, metals and the like can be cited. Accordingly, the memory function body can be formed so as to have a single layer or multilayer structure of, for example, an insulating film including a silicon nitride film, an insulating film including a conductive film or a semiconductor layer inside, an insulating film including one or more conductor or semiconductor dots, and an insulating film including a ferroelectric film where the internal charge is polarized due to an electrical field and this state is maintained. In particular, a large number of levels for trapping a charge exist in silicon nitride films, and therefore, the silicon nitride films are preferable as a material to be used for forming a memory function body because they can gain strong hysteresis properties. The silicon nitride films are also preferable for such use for the following reasons: the time for holding a charge is long; the holding properties are excellent because there are no problem of charge leaking due to the creation of a leak path; and silicon nitride films are standard materials for use in LSI processes.

Charge holding films such as silicon nitride films are placed on both sides of the gate electrode through with tunnel insulating film, and thereby, the reliability in terms of the holding memory can be increased. This is because silicon nitride films are made of an insulator, and therefore, even in the case where leaking of a charge occurs in a portion thereof, the charge in the entire silicon nitride film is not immediately lost. In addition, in the case where a plurality of memory cells are aligned and adjacent memory function bodies make contact with each other when the distance between memory cells becomes small, the information stored in each memory function body is not lost, unlike in the case where the memory function bodies are made of a conductor. Furthermore, a contact plug can be placed still closer to a memory function body, and in some cases, the contact plug can be placed so as to overlap with a memory function body, and therefore, miniaturization of memory cells becomes easy.

Here, it is not necessary for the charge holding films to be in film form in order to increase the reliability in terms of holding of memory, and the charge holding film may be present sporadically in the memory function body. Concretely, it is preferable for charge holding film to be dispersed in dot form in a material which can barely hold a charge, for example in silicon oxide.

In the case where the conductive film or semiconductor layer is used as the charge holding film, it is preferable for it to be placed through a tunnel insulating film, so that the charge holding film does not make direct contact with the semiconductor layer or the gate electrode.

An insulating film which includes a conductive film or a semiconductor layer inside is used as a memory function body, and thereby, the amount of charge injected into the conductor or the semiconductor can be freely controlled, and holding of multiple values becomes easier, which his preferable.

Furthermore, an insulating film including one or more conductors or semiconductor dots is used as a memory function body, and thereby, it becomes easy to carry out program/erase resulting from direct tunneling of a charge, and power consumption can be reduced, which is preferable.

In addition, a ferroelectric film, such as PZT or PLZT, where the direction of polarization is changed by an electrical field, may be used as the charge holding film. In this case, a substantial charge is generated on the surface of the ferroelectric film as a result of polarization, and this state is maintained. Accordingly, the same hysteresis properties as in a film for trapping a charge when a charge is supplied from outside the film having a memory function can be gained, and it is not necessary to inject a charge from outside the film when a ferroelectric film holds a charge, so that hysteresis properties can be gained only through the polarization of a charge within the film, and therefore, program/erase can be carried out at high speed, which is preferable.

Here, it is appropriate for the tunnel insulating film to have a function of making it difficult for a charge to escape, and silicon oxide films and the like can be cited as films having such a function of making it difficult for a charge to escape.

Charge holding films which are included in a memory function body are located on both sides of the gate electrode through a tunnel insulating film and placed on the semiconductor layer through a tunnel insulating film. It is preferable for the charge holding films on both sides of the gate electrode to be formed so as to cover the entirety or a portion of the side walls of the gate electrode through a tunnel insulating film. In the case of an example of application where the gate electrode has a recess in the lower end portion, the recess may be created so as to be completely or partially filled in with the charge holding films through a tunnel insulating film.

In addition, an insulating film that is thicker than the tunnel insulating film between the charge holding film and the side wall portion of the gate electrode can be used for the tunnel insulating film between the charge holding film and the semiconductor layer. The tunnel insulating films on the two side wall portions of the gate electrode may have the same thickness or different thicknesses. It is preferable for the tunnel insulating film between the charge holding film and the semiconductor layer to be 3 nm to 10 nm (converted to the value for a silicon oxide film through calculation). Meanwhile, it is preferable for the tunnel insulating film between the charge holding film and the side wall portion of the gate electrode to be 1 nm to 5 nm (converted to the value for a silicon oxide film through calculation). Furthermore, it is preferable for the tunnel insulating film between the charge holding film and the semiconductor layer to be 1.25 to 4 times thicker than the tunnel insulating film between the charge holding film and the side wall portion of the gate electrode.

The source/drain diffusion regions have a conductive type opposite to that of the channel region. The depth of the junction of the diffusion regions is not particularly limited, and can be appropriately adjusted in accordance with the performance or the like desired for the semiconductor memory device to be gained. In the case where the technology node is 180 nm, for example, the depth is 70 nm to 120 nm. Here, in the case where an SOI substrate is used as the semiconductor substrate, the diffusion regions may have a depth of junctions that is smaller than the film thickness of the semiconductor layer on the surface, but it is preferable for the diffusion regions to have a depth of junctions that is approximately the same as the film thickness of the semiconductor layer on the surface.

The diffusion regions may be placed so as to overlap with the ends of the gate electrode, placed so as to coincide with the ends of the gate electrode, or placed so as to be offset from the ends of the gate electrode. In the case of offset, ease of inversion in the offset region beneath the charge holding film when a voltage is applied to the gate electrode greatly changes depending on the amount of charge stored in the memory function body, and thus, the memory effects are improved and the short channel effects deteriorate, which is preferable. Here, too much offset makes the driving current between the diffusion regions (source/drain) significantly small, and therefore, it is preferable for the amount of offset, that is to say, the distance between one end of the gate electrode and the closer diffusion region in the direction of the gate length, to be smaller than the thickness of the charge holding film in the direction parallel to the direction of the gate length. It is preferable for at least a portion of the charge holding film in the memory function body to overlap with a portion of the diffusion region.

In the following embodiments, semiconductor memory devices (memory cells) of the present invention are described in further detail.

### Embodiment 1

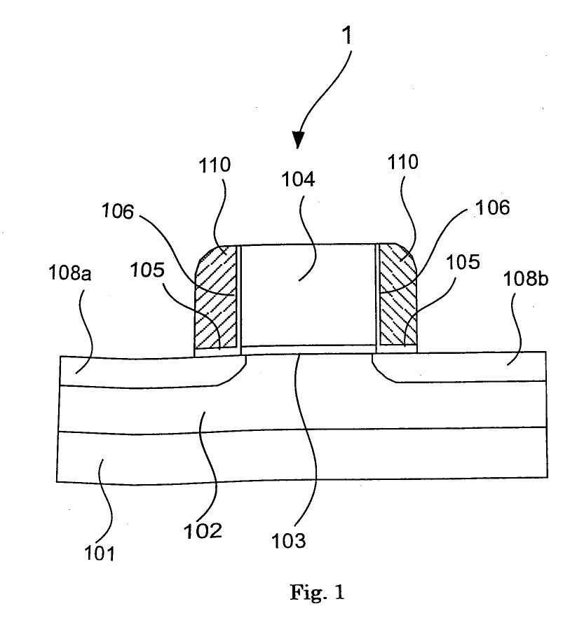

FIG. 1 shows a cross sectional structure of an example of a memory cell (memory cell 1). This memory cell 1 is formed in a P type well region 102 formed in the surface layer of a semiconductor substrate 101. A gate electrode 104 is formed on the P type well region 102 through a gate insulating film 103. Charge holding films 110 are formed on both sides of the above described gate electrode 104 as memory function bodies. Tunnel insulating films 106 and tunnel insulating films 105 are formed between the charge holding films 110 and the gate electrode 104, as well as between the charge holding films 110 and the P type well region 102, respectively. N type diffusion regions 108a and 108b function as a source region and a drain region, respectively. In the present embodiment, the charge holding films 110 are made of a silicon nitride film.

The charge holding films may be any film having a trapping level for holding a charge, and thus, are not limited to silicon nitride, but may be high dielectric films, such as hafnium oxide, aluminum hafnium oxide or aluminum oxide. The tunnel insulating films are made of a silicon oxide film.

The tunnel insulating films 105 which are formed on the side walls of the gate electrode 104, that is to say, between the N type diffusion region 108a and the charge holding film 110, as well as between the N type diffusion 108b and the charge holding film 110, are thicker than the tunnel insulating films 106 which are formed between the gate electrode 104 and the charge holding films 110. In the present embodiment, the film thickness of the tunnel insulating films 105 is 3 nm to 10 nm and the film thickness of the tunnel insulating films 106 is 1 nm to 5 nm. The tunnel insulating films 105 are thick enough to prevent the charge stored in the charge holding films 110 from being released to the N type diffusion regions 108a and 108b due to a tunnel phenomenon. Accordingly, the charge is prevented from being released to the P type well region 102 due to a tunnel phenomenon, while the charge holding films 110 are placed at locations close to the gate electrode 104, and therefore, an electrical field coming from the gate electrode can be efficiently applied to the N type diffusion regions 108a and 108b, which are the source/drain regions. Therefore, the memory cell can be operated at high speed.

Here, it is preferable for the film thickness of the tunnel insulating films 105 to be 1.25 to 4 times greater than the film thickness of the tunnel insulating film 106. The reason for this is described in detail in the following.

The smaller the film thickness of the tunnel insulating films 105 is, the more the effects of the charge stored in the charge holding films 110 can be conveyed to the P type well region 102; in other words, the shift in the threshold value required for the memory operation can be achieved with storage of a slight amount of charge. Accordingly, it is better to make the film thickness of the tunnel insulating films 105 small, from the point of view of the speed of the memory operation. However, if the film is thinner than 4 nm, it becomes easy for electrons which are held in the charge holding films 110 at the time of program to be released to the P type well region 102 due to a tunnel phenomenon. Therefore, it is preferable for the film thickness of the tunnel insulating films 105 to be no less than 4 nm. When the film thickness of the tunnel insulating films 105 is 4 nm and the film thickness of the tunnel insulating films 106 is no greater than 3.2 nm, the amount of gate disturbance and the amount of initial deterioration can be greatly reduced. As described above, the tunnel insulating films 105 should be 4 nm/3.2 nm=1.25 times or more thicker than the tunnel insulating films 106.

Meanwhile, it is preferable for the film thickness of the tunnel insulating films 106 to be no less than 1 nm. In the case of a film that is thinner than 1 nm, electrons which are stored in the charge holding films 110 at the time of program easily leak into the gate electrode 104. As a result, it is desirable for the tunnel insulating films 105 to have a thickness that is 4 nm/1 nm=4 times or less than that of the tunnel insulating films 106.

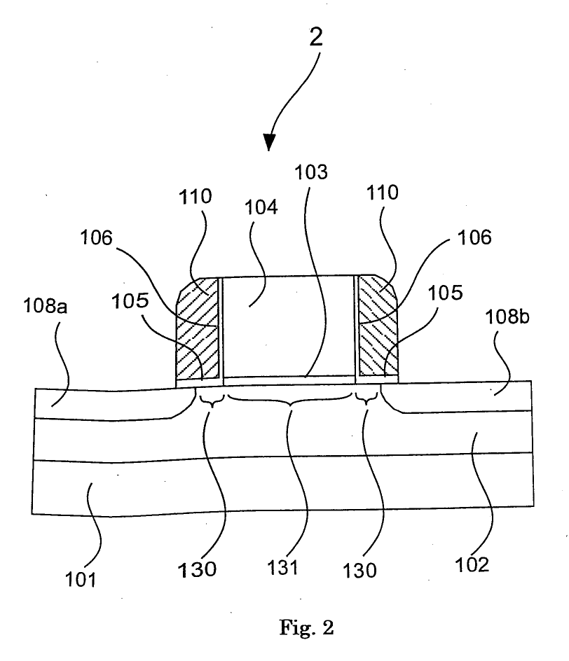

FIG. 2 shows a cross sectional structure of an example of a memory cell (memory cell 2). This memory cell 2 has an offset structure, unlike the memory cell 1. That is to say, N type diffusion regions 108a and 108b, which are source/drain regions, do not reach the channel region 131 beneath the gate electrode 104, and offset regions 130 beneath the charge holding films form a portion of the channel region. In the case where the memory state is “1” because electrons are trapped in the charge holding films 110, the resistance in the offset regions 130 can be easily and quickly increased so that the current that flows through the memory cell can be made small. Accordingly, high speed operation becomes possible, as compared to the memory cell 1.

In addition, in the case where the source/drain regions overlap with the gate electrode 104, as in the memory cell 1, holes, from among electrons and holes which are generated in the vicinity of the junctions at the time of erase, for example, are trapped in the gate insulating film 103, lowering the threshold voltage of the memory cell and making the short channel effects significant, and thus, the off leak current sometimes become great. In the memory cell 2, however, the source/drain regions do not overlap with the gate electrode 104, and therefore, only a very small amount of holes are trapped in the gate insulating film 103 at the time of erase. Accordingly, a memory cell having a small off leak current can be provided.

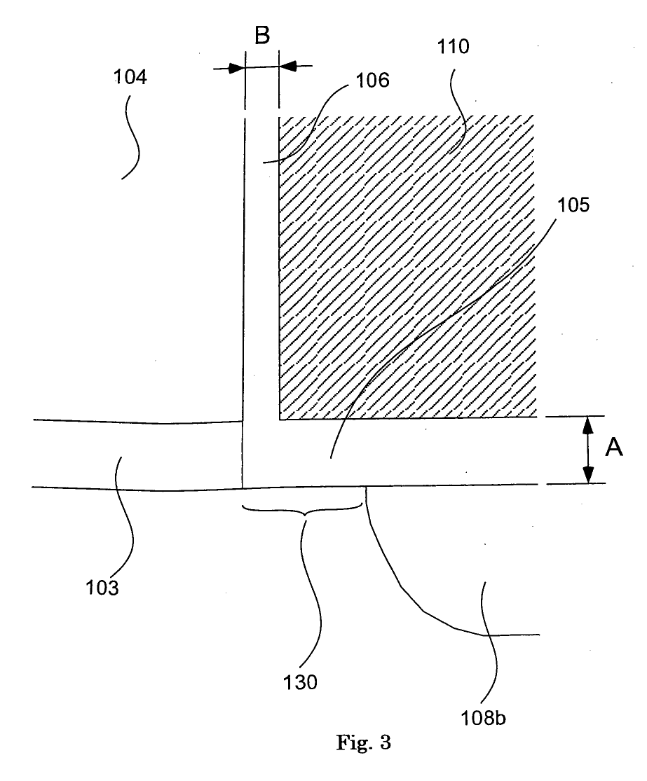

FIG. 3 is a diagram showing an enlarged end portion of the gate electrode 104 for illustrating the relationship in the film thickness between the tunnel insulating films 105 and the tunnel insulating films 106, as well as the positional relationship between the gate electrode 104 and the N type diffusion region 108b (existence of an offset region 130) in the memory cell 2. As shown in FIG. 3, the thickness A of the tunnel insulating film 105 formed between the charge holding film 110 and the semiconductor substrate is greater than the thickness B of the tunnel insulating film 106 which is formed between the gate electrode 104 and the charge holding film 110. This configuration in the film thickness is the same as in the case of the memory cell 1.

The gate electrode 104 and the N type diffusion regions 108a and 108b do not overlap, and an offset region 130 exists in between.

As described above, the tunnel insulating films 105 are thick enough to prevent the charge stored in the charge holding films 110 from being released to the N type diffusion regions 108a and 108b or the offset regions 130 due to a tunnel phenomenon, as in the memory cell 1. Accordingly, the charge is prevented from being released due to a tunnel phenomenon, while the charge holding films 110 are placed at a location close to the gate electrode 104, and therefore, an electrical field coming from the gate electrode can be efficiently applied to the offset regions 130, and the memory cell can be operated at high speed. In addition, the N type diffusion regions 108a and 108b do not overlap with the gate electrode 104 and are at a distance from the offset regions 130. Therefore, the effective channel length becomes greater by the width of the offset regions 130, as compared to the memory cell 1 having the same gate length. Accordingly, short channel effects are suppressed, and miniaturized memory cells can be implemented.

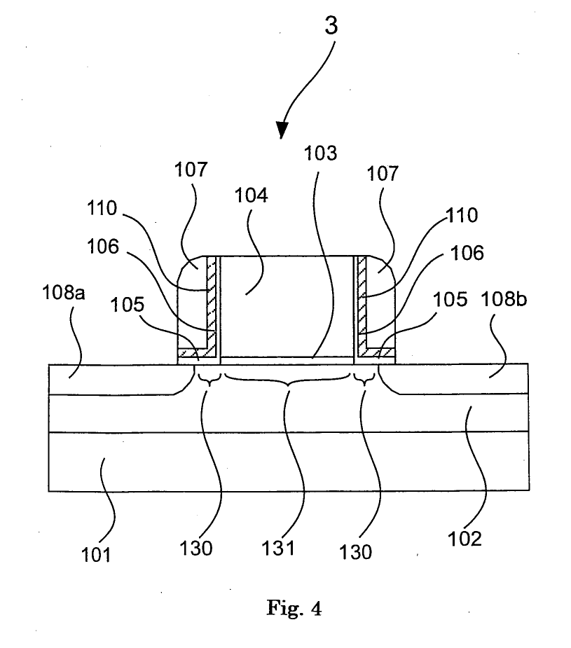

FIG. 4 shows another example of a memory cell (memory cell 3). This memory cell 3 is different from the memory cell 1 of FIG. 1 and the memory cell 2 of FIG. 2 in that respective memory function bodies have a trapping level for holding a charge and a structure where a charge holding film 110 made of a silicon nitride film is sandwiched between a tunnel insulating film 105 made of a silicon oxide film and a silicon oxide film 107 and between a tunnel insulating film 106 made of a silicon oxide film and a silicon oxide film 107. As shown in FIG. 4, a structure where a silicon nitride film is sandwiched between silicon oxide films is provided, and thereby, the efficiency of charge injection becomes high at the time of rewriting operation, making operation possible at a higher speed. In addition, the area of the charge holding films 110 is small in comparison with the memory cells 1 and 2, and therefore, the amount of charge stored (electrons at the time of program and holes at the time of erase) that diffuses through the charge holding films so as to become distanced from the offset regions 130 can be reduced. Accordingly, the charge that is stored in the charge holding films can be efficiently used to change the channel resistance in the offset regions 130 when the memory operates, and therefore, operation at a higher speed becomes possible.

### Embodiment 2

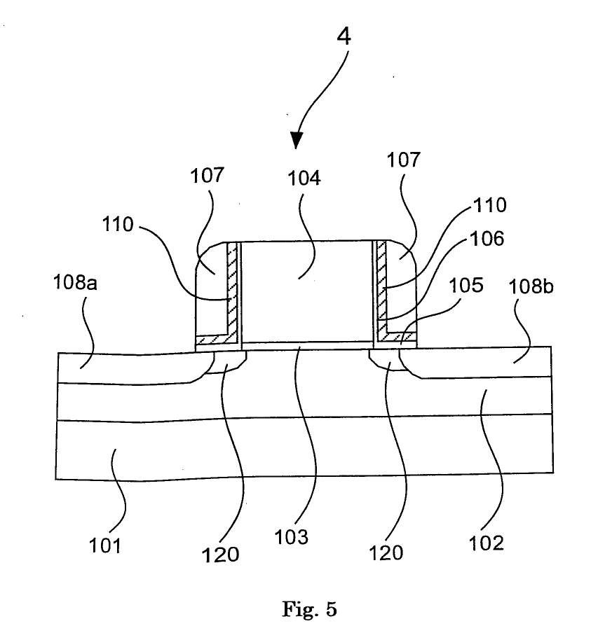

FIG. 5 shows a cross sectional structure of an example of a memory cell (memory cell 4). This memory cell 4 is gained by adding halo regions 120, into which a P type impurity has been doped, to the memory cell 3 of Embodiment 1. These halo regions 120 have an impurity concentration that is higher than that of the P type well region 102, and this concentration is within a range from 1×10¹⁸/cm³ to 1×10²⁰/cm³. The junctions between the halo region 120 and the N type diffusion region 108a, as well as between the halo region 120 and the N type diffusion region 108b, become steep, and therefore, the width of the depletion layers can be made small, and thus, the efficiency with which a charge is generated at the time of program and erase can be increased. Accordingly, it becomes possible to increase the speed and lower the voltage of the memory cell.

In addition, portions where a charge is generated can be limited to an area somewhere along the gate length, by reducing the width of the depletion layers. Accordingly, even after repeated rewriting/erase, deterioration of the reliability in terms of holding of memory, due to the recombination of electrons and holes in the charge holding films 110, can be prevented.

### Embodiment 3

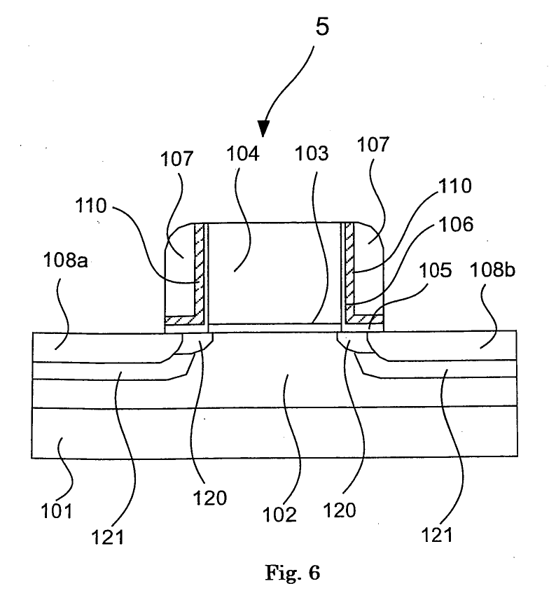

FIG. 6 shows a cross sectional structure of an example of a memory cell (memory cell 5). This memory cell 5 is gained by adding N type diffusion regions 121 beneath the N type diffusion regions 108a and 108b to the memory cell 4 of Embodiment 2. These N type diffusion regions 121 have an impurity concentration that is lower than that of the N type diffusion regions 108a and 108b, and it is preferable for this concentration to be no greater than one quarter of the impurity concentration of the halo regions 120, which is 1×10¹⁷/cm³ to 2×10¹⁹/cm³. The impurity that forms these N type diffusion regions 121 reaches the halo regions 120 at the time of formation of these regions so as to offset the P type impurity in the halo regions 120, and thus, should be set to have such a concentration as not to damage the steepness of the junctions between the N type diffusion region 108a and the halo region 120, as well as between the N type diffusion region 108b and the halo region 120. This concentration is one quarter of that in the halo regions 120.

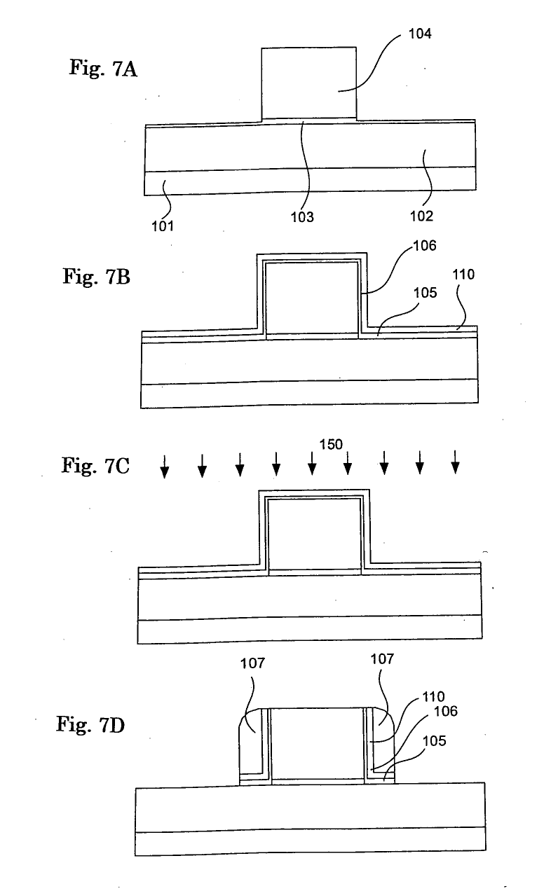

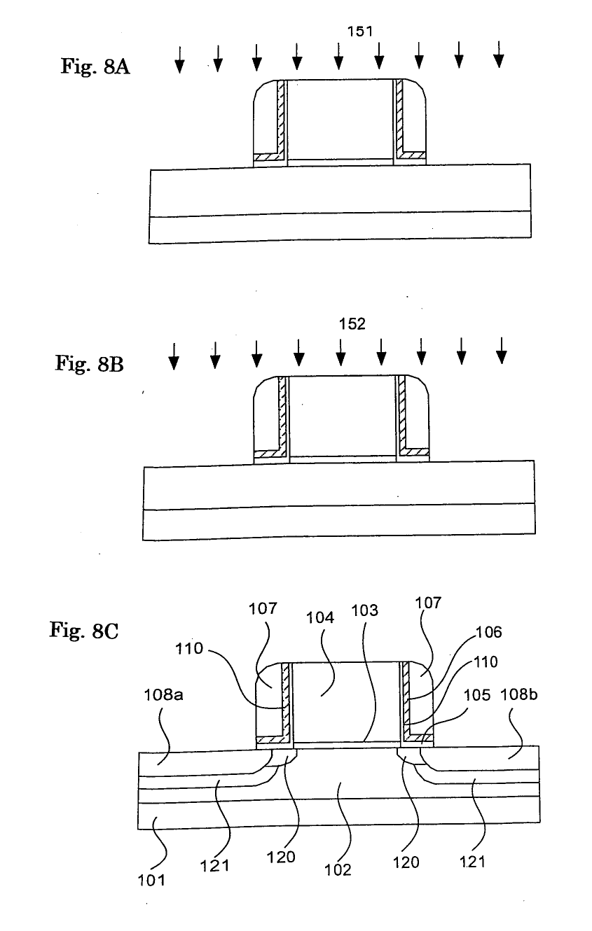

Next, in reference to FIGS. 7A to 7D and FIGS. 8A to 8C, a manufacturing method for the memory cell 5 is described. Here, though a manufacturing method for a memory cell 5 is shown, the memory cells 1 to 4 can be formed omitting or modifying a portion of this manufacturing method for a memory cell 5, and therefore, only the manufacturing method for a memory cell 5 is described. Though the present process for formation shows a case where N channel transistors are formed, P channel transistors can be formed in the same manner as in this example simply by reversing the conductivity type of the components.

First, as shown in FIG. 7A, a P type well region 102 is formed in a semiconductor substrate 101 in accordance with a well known method. Next, though not shown, formation of element isolation region and ion implantation for adjusting the threshold voltage are carried out. The P well region 102 may be formed after the formation of the element isolation region.

Next, a gate insulating film (gate oxide film) 103 and a gate electrode 104 are formed in accordance with a well known method. As for the film thickness, the gate insulating film 103 is 5 nm to 10 nm, and the gate electrode 104 is 150 nm to 300 nm. Here, the process for the formation of the gate electrode 104 is described.

After a polycrystal silicon film has been formed on the gate insulating film 103 in accordance with a low pressure chemical vapor deposition method (LPCVD method), the polycrystal silicon film is processed in accordance with well known lithographic technology and dry etching technology, and thereby, the gate electrode 104 is formed. At this time, the gate insulating film 103 remains in the region from which the polycrystal silicon film was removed through dry etching. As for the thickness of this film, a film thickness of no less than 7 nm remains when the film thickness of the gate insulating film is 8 nm.

Next, as shown in FIG. 7B, a silicon oxide film, which becomes tunnel insulating films, is formed in accordance with a thermal oxidation method. At this time, though the tunnel insulating films are formed in a conventional way after the above described remaining gate insulating film has entirely been removed using diluted hydrofluoric acid, the gate insulating film is not entirely removed, but left before shifting to the process for forming the tunnel insulating film according to the present invention. The method for forming a tunnel insulating film is described in the following, including the pre processing.

As described above, though the gate insulating film is etched by less than 1 nm through dry etching for the polycrystal silicon film, a layer damaged by ions remains on the top of the gate insulating film because reactive ion etching (RIE) is used. In the case where the tunnel insulating film is formed with such a damaged layer being left, the tunnel insulating film has many defects, which is not preferable from the point of view of reliability, and therefore, the damaged layer is removed using diluted hydrofluoric acid. As a result, the gate insulating film of 8 nm is reduced to approximately 5 nm, through the ion etching and this process using diluted hydrofluoric acid.

Concretely, a process of 10 seconds can be carried out with diluted hydrofluoric acid of 0.5%, and thereby, the damaged layer on top of the gate insulating film can be removed. The inventors confirmed through experiment that the layer damaged through dry etching for the polycrystal silicon film is 2 nm to 3 nm, and this damaged layer can be easily removed through a process of 7 seconds to 17 seconds using diluted hydrofluoric acid of 0.5%. In the case where the above described process is carried out on a thermal oxide film having no damaged layer, the thickness of the film that is lost to etching is 0.4 nm to 1 nm, while in the case of the damaged layer, the density becomes smaller, making the etching rate greater, and therefore, the damaged layer can be removed in this process.

After this, a tunnel insulating film (silicon oxide film) is formed in accordance with a thermal oxidation method. The film thickness gained through thermal oxidation is 2 nm to 4 nm. As a result of this thermal oxidation, tunnel insulating films 106 having a thickness of 2 nm to 4 nm and tunnel insulating films 105 having a thickness of 5 nm to 7 nm are formed on the side walls of the gate electrode 104 and the P type well region 102, respectively. Because a thermal oxidation method is used, the tunnel insulating films 105 do not have a film thickness which is equal to the sum of the thickness of the remaining gate insulating films and the thickness of the thermal oxidation film.

As described above, the respective tunnel insulating films are formed so that the film thickness of the tunnel insulating films 105 on the P type well region 102 becomes greater than that of the tunnel insulating films 106 on the side walls of the gate electrode 104. Though in the present embodiment, the film thickness of the gate insulating film 103 is 8 nm, the invention is not limited to this, and an appropriate film thickness should be set on the basis of the voltage for operation and the required dimensions for the element. As for the voltage for operation, it is necessary for the film thickness to be set so that there is no lack of withstand voltage. As for the dimensions of the element, the thickness of the gate insulating film has a large impact on the short channel effects, and therefore, the thickness of the gate insulating film is small in the case where a miniaturized memory cell is desired to be gained, and the thickness of the gate insulating film may be great in the case where no miniaturized memory cell is required.

In addition, it is preferable for the film thickness of the tunnel insulating films 105 which are formed in the P type well region 102 to be set at approximately 4 nm to 8 nm. In the case where the film is thinner than 4 nm, a charge tunnels from the charge holding films 110 which are made of a silicon nitride film to the P type well region 102, and thus, the state of storage cannot be maintained. In the case where the film is thicker than 8 nm, it becomes difficult for the charge held in the charge holding films 110 to influence the potential of the offset regions 131 formed in the P type well region 102, and thus, increase in speed is prevented. Accordingly, it is preferable for the film thickness of the tunnel insulating films 105 to be approximately 4 nm to 8 nm.

It is preferable for the film thickness of the tunnel insulating films 106 formed on the side walls of the gate electrode 104 to be approximately 2 nm to 5 nm. As a result of the removal of the damaged layer when the gate insulating film 103 after the damaged layer has been formed is converted to tunnel insulating films 105 through thermal oxidation and this process of thermal oxidation, highly reliable tunnel insulating films 105 are gained, and thus, in the case where the film thickness is smaller than 2 nm during this process for thermal oxidation, it is difficult to gain highly reliable tunnel insulating films 105. In addition, in the case where the film is thicker than 5 nm, deterioration of the reliability, which is the above described gate disturbance, is caused. Therefore, it is preferable for the film thickness of the tunnel insulating films 106 to be approximately 2 nm to 5 nm.

Next, charge holding films 110 are formed in accordance with an LPCVD method. The charge holding films 110 are set to have a film thickness of 3 nm to 20 nm.

Next, as shown in FIG. 7C, impurity ions 150 are implanted for the formation of halo regions 120. Under the conditions for this implantation, boron ions are implanted with energy of 10 keV to 20 keV, and the amount for implantation is 1×10¹³/cm² to 5×10¹⁴/cm².

Next, as shown in FIG. 7D, etch-back is carried out after a silicon oxide film has been deposited in accordance with a CVD method, and thereby, silicon oxide films 107 are formed. Though in FIG. 7D, etch-back is carried out under such conditions that the charge holding films 110, as well as the tunnel insulating films 105 and 106 on the gate electrode 104 and the source/drain regions, are removed, etch-back may be carried out under such conditions that these films remain, that is to say, etch-back may be carried out only on the silicon oxide film 107.

Next, as shown in FIG. 8A, N type impurity ions 151 for the formation of N type diffusion regions 108a and 108b, which become source/drain diffusion regions, are implanted in accordance with a well known ion implantation method under conditions where the energy is 5 keV to 60 keV and the amount for implantation is 1×10¹⁵/cm² to 1×10¹⁶/cm².

Next, as shown in FIG. 8B, N type impurity ions 152 for the formation of N type diffusion regions 121 having a low impurity concentration are implanted in accordance with a well known ion implantation method under conditions where the type of ions implanted is phosphorous, the energy is 50 keV to 100 keV and the amount for implantation is 2×10¹²/cm² to 1×10¹⁴/cm².

It is desirable for the energy under these conditions for implantation to be set so that the range (distance between the surface and the peak of concentration in the direction of the depth of implantation) matches with the depth of the junctions of the N type diffusion regions 108a and 108b. It is desirable for the amount for implantation to be set so that the concentration in the silicon substrate after activation becomes no higher than one quarter of the concentration in the halo regions 120.

As described in Embodiment 1, thin N type diffusion regions 121 reach the halo regions 120 so that offset is caused due to the boron within the halo regions 120. In the case where this concentration is no less than one quarter of that in the halo regions 120, however, the speed of operation of the memory cell sometimes becomes slow under the influence of the steepness of the junctions between the halo region 120 and the N type diffusion region 108a, as well as between the halo region 120 and the N type diffusion region 108b. In the case where the concentration is less than one quarter of that in the halo regions 120, however, the speed of operation of the memory cell is not affected by the steepness of the junctions. Accordingly, a memory cell which can be operated at high speed can be implemented.

Next, as shown in FIG. 8C, an annealing process for activating the implanted impurity is carried out. In the present embodiment, a rapid thermal annealing (RTA) is carried out, and thereby, the implanted impurity is activated, so that N type diffusion regions 108a and 108b, halo regions 120 and N type diffusion regions 121 are formed. A memory cell can be gained in the above described process. Next, though not shown, an interlayer insulating film and metal wire can be formed in accordance with a well known technology.

As described above, in the process for formation according to the present embodiment, a memory cell where the tunnel insulating films 105 formed on the semiconductor substrate are thicker than the tunnel insulating films 106 formed on the side wall portions of the gate electrode 104 can be formed without using any special process. Accordingly, the problem of gate disturbance, which is a problem in the prior art, can be prevented, and increase in the current on the program side can be restricted, so that a memory cell having a large memory window can be implemented. In addition, though it is necessary to increase the gate width in order to compensate for the reduction in current resulting from gate disturbance according to the prior art, such a condition is less necessary according to the present invention, and therefore, a highly integrated nonvolatile memory can be implemented by miniaturizing memory cells.

According to the semiconductor memory device of the present invention, the memory function bodies are formed independently of the gate insulating film, and are formed on both sides of the gate electrode. Therefore, a two-bit operation is possible. Furthermore, the memory function bodies are separated from each other by the gate electrode, and therefore, interference at the time of rewriting can be effectively restricted. In addition, the memory function bodies are separated from each other, and therefore, short channel effects can be restricted, by making the gate insulating film thin. Accordingly, miniaturization of the device becomes easy.

In addition, the tunnel insulating films between the charge holding films and the semiconductor layer in the semiconductor memory device of the present invention has a film thickness that is greater than that of the tunnel insulating films on the side wall portions of the gate electrode, and therefore, increase in the current on the program side can be restricted while restricting gate disturbance. Accordingly, the gate can be formed so as to have a small gate width, and therefore, a highly integrated semiconductor memory device can be implemented through miniaturization.

What is claimed is:

1. A semiconductor memory device comprising:
a semiconductor layer;
a gate electrode formed on the semiconductor layer through a gate insulating film;
a channel region provided beneath the gate electrode;
source/drain diffusion regions having a conductivity type opposite to that of the channel region and provided on both sides of the channel region; and
memory function bodies having a function of holding a charge and formed on at least both sides of the gate electrode,
wherein the memory function body is formed of a charge holding film and a tunnel insulating film,
the tunnel insulating film exists on the side wall portion of the gate electrode and between the charge holding film and the semiconductor layer, and
the tunnel insulating film between the charge holding film and the semiconductor layer is thicker than the tunnel insulating film between the charge holding film and the side wall portion of the gate electrode.

2. The semiconductor memory device of claim 1, wherein the charge holding film is made of an insulating material and the memory function body is formed so as to at least partially overlap a portion of the source/drain diffusion regions.

3. The semiconductor memory device of claim 1, wherein the gate electrode and the source/drain diffusion regions separate in the direction of a gate length.

4. The semiconductor memory device of claim 1, wherein the tunnel insulating film between the charge holding film and the semiconductor layer is made 1.25 to 4 times thicker than the tunnel insulating film on the side wall portion of the gate electrode.

5. The semiconductor memory device of claim 1, wherein the charge holding film is a silicon nitride film.

6. The semiconductor memory device of claim 1, wherein the tunnel insulating film is a silicon oxide film.

7. The semiconductor memory device of claim 1, wherein the thickness of the tunnel insulating film between the charge holding film and the semiconductor layer is 3 nm to 10 nm, and the thickness of the tunnel insulating film on the side wall portion of the gate electrode is 1 to 5 nm.

8. The semiconductor memory device of claim 1, further comprising first diffusion regions placed between the channel region and source/drain diffusion regions, wherein conductivity types of the first diffusion regions and the channel region are the same, and an impurity concentration of the first diffusion regions is higher than that of the channel region.

9. The semiconductor memory device of claim 1, further comprising second diffusion regions placed beneath the source/drain diffusion regions, wherein conductivity types of the second diffusion regions and the source/drain diffusion regions are the same, and an impurity concentration of the second diffusion regions is lower than that of the source/drain diffusion regions.

10. The semiconductor memory device of claim 1, wherein the concentration of the second diffusion regions is no greater than one quarter of that of the first diffusion regions.
